(19) United States
(12) Patent Application Publication
(10) Pub. No.: US 2026/0023131 A1
(43) Pub. Date: Jan. 22, 2026

(54) Fault Detection of Parallel-Connected Cell Groups Using Differential Voltage Analysis

(71) Applicants: THE REGENTS OF THE UNIVERSITY OF MICHIGAN, Ann Arbor, MI (US); LG ENERGY SOLUTION, LTD., Seoul (KR)

(72) Inventors: Anna Stefanopoulou, Ann Arbor, MI (US); Clement Wong, Ann Arbor, MI (US); Jason Siegel, Ann Arbor, MI (US); Seung Yoon Yang, Seoul (KR); Jeesoon Choi, Seoul (KR); Heejun Jin, Seoul (KR)

(21) Appl. No.: 19/275,296

(22) Filed: Jul. 21, 2025

Related U.S. Application Data
(60) Provisional application No. 63/673,898, filed on Jul. 22, 2024.

(51) Int. Cl. G01R 31/396; G01R 31/36

(52) U.S. Cl. CPC G01R 31/396; G01R 31/3648

(57) ABSTRACT

Devices and methods are disclosed for detecting or ruling out a fault in a battery module including one or more battery cells. An electrical device comprises a battery module; a voltage sensor and a current sensor operatively coupled to each group of parallel-connected battery cells; and a battery management system including a controller in electrical communication with each voltage sensor and each current sensor. The controller executes a program to: calculate a differential voltage curve for each group of parallel-connected battery cells, determine a differential voltage point on the differential voltage curves wherein each differential voltage point is at a local peak, determine one or more shape characteristics from differential voltage data surrounding each local peak, and pass each shape characteristic of each local peak into a model to detect or rule out a fault characteristic in each group of parallel-connected battery cells.

### CROSS-REFERENCES TO RELATED APPLICATIONS

This application is based on, claims benefit of, and claims priority to U.S. Patent Application No. 63/673,898 filed on Jul. 22, 2024, which is hereby incorporated by reference herein in its entirety for all purposes.

### STATEMENT REGARDING FEDERALLY SPONSORED RESEARCH

Not Applicable.

### BACKGROUND OF THE INVENTION

### 1. Field of the Invention

This invention relates to devices and methods for detecting or ruling out a fault in a battery module including one or more groups of parallel-connected battery cells.

### 2. Description of the Related Art

An energy storage system (ESS) typically includes a plurality of batteries and a bi-directional inverter though which direct current energy storage devices such as batteries may be electrically connected to an alternating current external system, such as a power grid. The ESS may be used to temporarily store energy produced by renewable power sources (e.g., photovoltaic (PV) sources and/or wind turbines). When the ESS is coupled to a PV source or wind turbines that can produce electrical power in excess of the grid requirement (e.g., a PV field on a sunny day or a wind turbine on a windy day), the excess power can be used to charge the ESS batteries. Conversely, when the grid requires power greater than what is provided by the renewable sources, the ESS batteries may be discharged to provide power to the grid. In a typical ESS, the battery cells connected in parallel into small groups called modules. Battery packs are then built from a plurality of the battery modules by interconnecting the battery modules in series within racks of a container that provides structural support and connectivity with the inverter.

Most electric vehicle (EV) battery packs are also built from groups of battery cells housed in modules interconnected within an enclosure that provides structural support and connectivity with the rest of the drivetrain. Cell-to-module batteries configure the cells into small groups called modules. The modules are then assembled to create a full vehicle's battery pack.

Battery energy storage systems and electric vehicles are often powered by

lithium-ion battery modules, which are composed of many individual lithium-ion cells connected in parallel. These individual cells in a module can degrade at different rates. Identifying whether any of the individual cells exhibit fault characteristics is critical for the module's safety. However, such identification is challenging because manufacturers typically do not place current sensors for each cell within a parallel-connected group in the module, leaving no direct measurement of each cell's behavior.

What is needed therefore is improved devices and methods for detecting or ruling out a fault in a battery module including one or more battery cells.

### SUMMARY OF THE INVENTION

The present disclosure meets the foregoing needs by providing a method that detects that if a parallel-connected group of cells within a battery module may contain an individual cell exhibiting fault characteristics, using time series voltage and current measurements from the groups in the module. This method calculates features of the differential voltage over capacity curve (dV/dQ) for each parallel cell group within a module whenever the module undergoes low-rate current dynamic discharge or charge, such as under constant current or constant power conditions. The calculated features are characteristics of the shape of the peaks in the dV/dQ curve, namely the peaks' height, skewness, width, location relative to voltage, and their daily changes. The method then normalizes these feature values relative to other parallel groups in the module. Finally, the method classifies whether a parallel-connected cell group in a module exhibits fault characteristics, by a statistical model trained on feature values of parallel cell groups in battery modules with known fault classification.

Cell groups in battery modules with a known fault classification exhibit statistically significant differences in the feature values that characterize the shape of the groups' dV/dQ curve peaks, compared to cells labeled as having non-fault characteristics. Differences in the dV/dQ curve peaks' shape are attributed to single-cell inhomogeneity and/or imbalanced aging of capacity and resistance within the parallel cell group.

In one aspect, the present disclosure provides an electrical device comprising: a battery module including one or more groups of parallel-connected battery cells; a voltage sensor operatively coupled to each group of parallel-connected battery cells in order to measure a voltage level of each group of parallel-connected battery cells; a current sensor operatively coupled to each group of parallel-connected battery cells in order to measure an amount of current drawn from each group of parallel-connected battery cells; and a battery management system including a controller in electrical communication with each voltage sensor and each current sensor. The controller can be configured to execute a program stored in the controller to: (i) receive a plurality of voltage values from each voltage sensor, (ii) receive a plurality of current values from each current sensor, wherein each current value is associated with one of the voltage values, (iii) calculate a plurality of total discharge values for each group of parallel-connected battery cells, wherein each total discharge value is associated with one of the current values, (iv) calculate a differential voltage curve for each group of parallel-connected battery cells using the voltage values and the total discharge values, (v) determine a differential voltage point on the differential voltage curve for each group of parallel-connected battery cells wherein each differential voltage point is at a local peak; (vi) determine one or more shape characteristics from differential voltage data surrounding each local peak; and (vii) pass each shape characteristic of each local peak into a model to detect or rule out a fault characteristic in each group of parallel-connected battery cells, the model including shape characteristics of local peaks of one or more differential voltage curves from one or more reference battery modules.

In another aspect, the present disclosure provides a method for detecting or ruling out a fault in a battery module including one or more groups of parallel-connected battery cells. The method comprises: (a) measuring voltage in each group of parallel-connected battery cells; (b) measuring current drawn from each group of parallel-connected battery cells; and (c) detecting or ruling out in a controller a fault characteristic in each group of parallel-connected battery cells based on: (i) the voltage measured, (ii) the current measured, (iii) a total discharge calculated, (iv) a differential voltage curve calculated based on the voltage measured and the total discharge calculated, (v) a differential voltage point on the differential voltage curve for each group of parallel-connected battery cells wherein each differential voltage point is at a local peak, wherein each local peak has a shape with one or more shape characteristics, and (vi) a comparison of each shape characteristic of each local peak to a predetermined shape characteristic in a model, wherein the model includes shape characteristics of local peaks of one or more differential voltage curves from one or more reference battery modules.

In yet another aspect, the present disclosure provides a method in a data processing system comprising at least one processor and at least one memory, the at least one memory comprising instructions executed by the at least one processor to implement a battery module fault detection system. The method comprises: (a) receiving a plurality of voltage values from a voltage sensor operatively coupled to each group of parallel-connected battery cells of a battery module in order to measure a voltage level of each group of parallel-connected battery cells; (b) receiving a plurality of current values from a current sensor operatively coupled to each group of parallel-connected battery cells in order to measure an amount of current drawn from each group of parallel-connected battery cells, each current value being associated with one of the voltage values included in the plurality of voltage values; (c) calculating a plurality of total discharge values, each total discharge value being associated with one of the current values included in the plurality of current values; (d) calculating a differential voltage curve based on the voltage values and the total discharge values; (e) determining a differential voltage point on the differential voltage curve for each group of parallel-connected battery cells wherein each differential voltage point is at a local peak, wherein each local peak has a shape with one or more shape characteristics; and (f) passing each shape characteristic of each local peak into a model to detect or rule out a fault characteristic in each group of parallel-connected battery cells, the model including the shape characteristics of local peaks of one or more differential voltage curves from one or more reference battery modules.

These and other features, aspects, and advantages of the present invention will become better understood upon consideration of the following detailed description, drawings, and appended claims.

### BRIEF DESCRIPTION OF THE DRAWINGS

FIG. 1 shows a schematic of a module and parallel-connected group of cells.

FIG. 1A is a schematic of a non-limiting example lithium ion battery that can used in the method of the present disclosure.

FIG. 2 shows features characterizing shape of the peaks of parallel-connected group's dV/dQ.

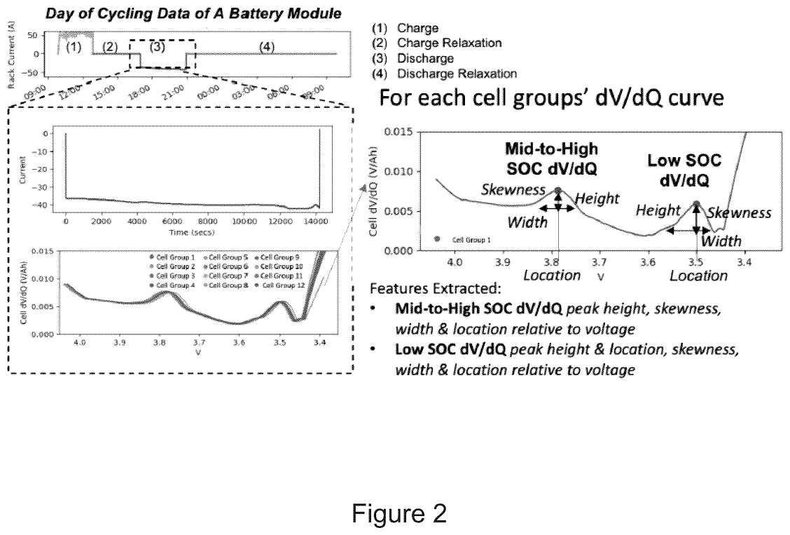

FIG. 3 shows a flow chart of a fault detection algorithm according to one non-limiting example method of the present disclosure.

FIG. 4 shows a relationship between dV/dQ shape features with imbalanced aging in capacity and resistance within a 2P cell group.

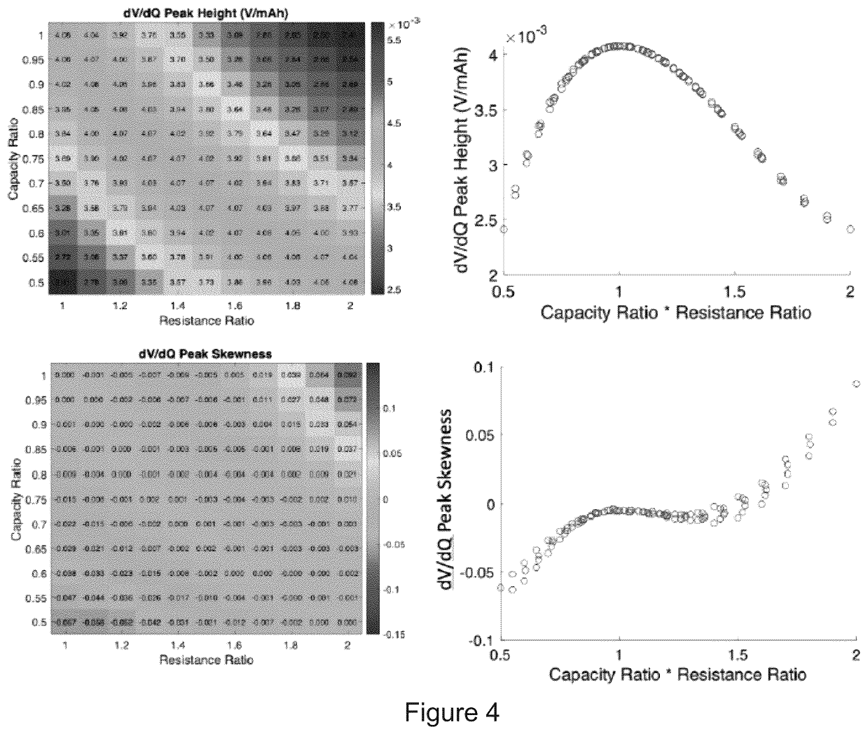

FIG. 5 shows fault classification using a multivariate Gaussian model from a model training phase according to one non-limiting example method of the present disclosure.

FIG. 6 shows in the left panel, precision-recall tradeoff for different epsilon values, and in the right panel, fault classification using a multivariate Gaussian model from the model training phase according to one non-limiting example method of the present disclosure.

### DETAILED DESCRIPTION OF THE INVENTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items.

The following discussion is presented to enable a person skilled in the art to make and use embodiments of the invention. Various modifications to the illustrated embodiments will be readily apparent to those skilled in the art, and the generic principles herein can be applied to other embodiments and applications without departing from embodiments of the invention. Thus, embodiments of the invention are not intended to be limited to embodiments shown, but are to be accorded the widest scope consistent with the principles and features disclosed herein. Skilled artisans will recognize the examples provided herein have many useful alternatives and fall within the scope of embodiments of the invention.

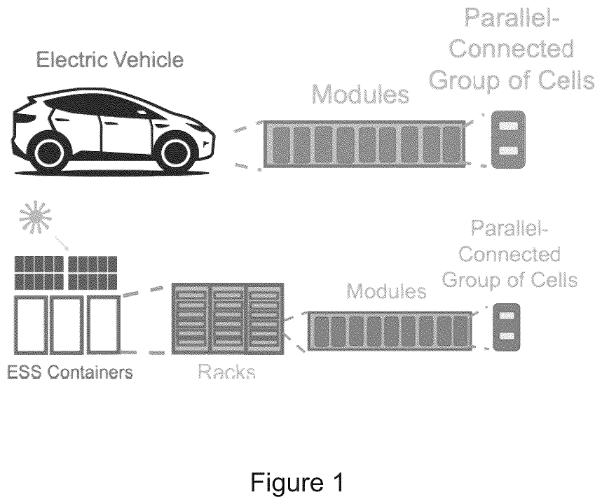

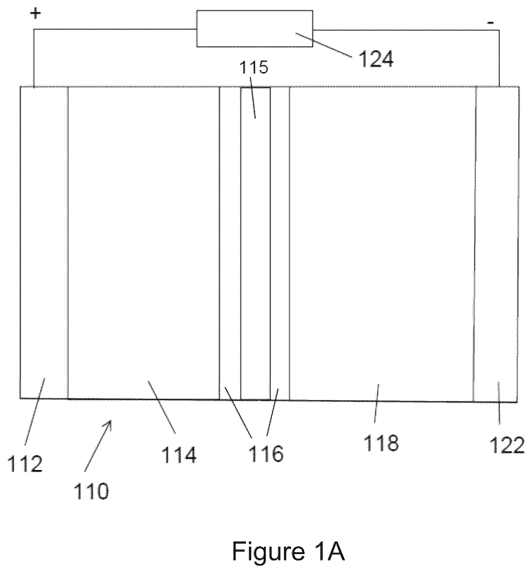

FIG. 1A shows a non-limiting example of a lithium ion battery 110 that can be used in a method of the present disclosure. The lithium ion battery 110 includes a current collector 112 in contact with a cathode 114. At least a portion of an amount of a liquid electrolyte 116 is arranged between the cathode 114 and an anode 118, which is in contact with a current collector 122. A separator 115 keeps the cathode 114 and the anode 118 from touching but allows metal ions through. The current collectors 112 and 122 of the electrochemical cell 110 may be in electrical communication with an electrical component 124. The electrical component 124 could place the electrochemical cell 110 in electrical communication with an electrical load that discharges the battery or a charger that charges the battery.

A suitable active material for the cathode 114 of the lithium ion battery 110 is a lithium host material capable of storing and subsequently releasing lithium ions.

An example cathode active material is a lithium metal oxide wherein the metal is one or more aluminum, cobalt, iron, manganese, nickel, and vanadium. Non-limiting example lithium metal oxides are LiCoO₂ (LCO), LiFeO₂, LiMnO₂ (LMO), LiMn₂O₄, LiNiO₂ (LNO), LiNiₓCO_{y}O₂, LiMnₓCo_{y}O₂, LiMnₓNi_{y}O₂, LiMnₓNi_{y}O₄, LiNiₓCo_{y}Al₂O₂ (NCA), LiNi_{1/3}Mn_{1/3}Co_{1/3}O₂ and others. Another example of cathode active materials is a lithium-containing phosphate having a general formula LiMPO₄ wherein M is one or more of cobalt, iron, manganese, and nickel, such as lithium iron phosphate (LFP) and lithium iron fluorophosphates. The cathode can comprise a cathode active material having a formula LiNiₓMn_{y}Co_{z}O₂, wherein x+y+z=1 and x:y:z=1:1:1 (NMC 111), x:y:z=4:3:3 (NMC 433), x:y:z=5:2:2 (NMC 522), x:y:z=5:3:2 (NMC 532), x:y:z=6:2:2 (NMC 622), or x:y:z=8:1:1 (NMC 811). The cathode active material can be a mixture of any number of these cathode active materials.

A suitable active material for the anode 118 of the lithium ion battery 110 is a lithium host material capable of incorporating and subsequently releasing the lithium ion such as graphite (artificial, natural), a lithium metal oxide (e.g., lithium titanium oxide), hard carbon, a tin/cobalt alloy, or silicon/carbon. The anode active material can be a mixture of any number of these anode active materials.

An example electrolyte 116 of the electrochemical cell 110 comprises a lithium compound in an organic solvent. The lithium compound may be selected from LiPF₆, LiBF₄, LiClO₄, lithium bis (fluorosulfonyl) imide (LiFSI), LiN(CF₃SO₂)₂ (LiTFSI), and LiCF₃SO₃ (LiTf). The organic solvent may be selected from carbonate based solvents, ether based solvents, ionic liquids, and mixtures thereof. The carbonate based solvent may be selected from the group consisting of dimethyl carbonate, diethyl carbonate, ethyl methyl carbonate, dipropyl carbonate, methylpropyl carbonate, ethylpropyl carbonate, methylethyl carbonate, ethylene carbonate, propylene carbonate, and butylene carbonate; and the ether based solvent may be selected from the group consisting of diethyl ether, dibutyl ether, monoglyme, diglyme, tetraglyme, 2-methyltetrahydrofuran, tetrahydrofuran, 1,3-dioxolane, 1,2-dimethoxyethane, and 1,4-dioxane.

During normal operation, the principal functions of the separator 115 are to prevent electronic conduction (i.e., shorts or direct contact) between the anode and cathode while permitting ionic conduction via the electrolyte. A suitable material for the separator 115 of the electrochemical cell 110 is porous polypropylene, porous polyethylene, or blends or layers thereof. The separator may comprise the protective layer described in the present disclosure, so that the protective layer functions as the separator.

Alternatively, the separator 115 and the liquid electrolyte 116 of the electrochemical cell 110 may be replaced with a solid electrolyte material. In non-limiting example solid electrolyte materials, the solid electrolyte material comprises an electrolyte material having the formula LiᵤReᵥM_{w}AₓO_{y}, wherein
Re can be any combination of elements with a nominal valance of +3 including La, Nd, Pr, Pm, Sm, Sc, Eu, Gd, Tb, Dy, Y, Ho, Er, Tm, Yb, and Lu;
M can be any combination of metals with a nominal valance of +3, +4, +5 or +6 including Zr, Ta, Nb, Sb, W, Hf, Sn, Ti, V, Bi, Ge, and Si;
A can be any combination of dopant atoms with nominal valance of +1, +2, +3 or +4 including H, Na, K, Rb, Cs, Ba, Sr, Ca, Mg, Fe, Co, Ni, Cu, Zn, Ga, Al, B, and Mn;
u can vary from 3-7.5;
v can vary from 0-3;
w can vary from 0-2;
x can vary from 0-2; and
y can vary from 11-12.5.

The electrolyte material may be a lithium lanthanum zirconium oxide. The electrolyte material may have the formula Li_{6.25}La_{2.7}Zr₂Al_{0.25}O₁₂.

Another example solid state electrolyte can include any combination oxide or phosphate materials with a garnet, perovskite, NaSICON, or LiSICON phase. The solid state electrolyte of the lithium ion battery 110 can include any solid-like material capable of storing and transporting ions between the anode 118 and the cathode 114.

The current collector 112 and the current collector 122 can comprise a conductive material. For example, the current collector 112 and the current collector 122 may comprise molybdenum, aluminum, nickel, copper, combinations and alloys thereof or stainless steel.

The present invention is not limited to lithium ion batteries. In alternative embodiments, a suitable anode can comprise magnesium, sodium, or zinc. Suitable alternative cathode and electrolyte materials can be selected for such magnesium ion batteries, sodium ion batteries, or zinc ion batteries. For example, a sodium ion battery can include: (i) an anode comprising sodium ions, (ii) a solid state electrolyte comprising a metal cation-alumina (e.g., sodium-β-alumina or sodium-β″-alumina), and (iii) a cathode comprising an active material selected from the group consisting of layered metal oxides, (e.g., NaFeO, NaMnO, NaTiO, NaNiO, NaCrO, NaCoO, and NaVO) metal halides, polyanionic compounds, porous carbon, and sulfur containing materials.

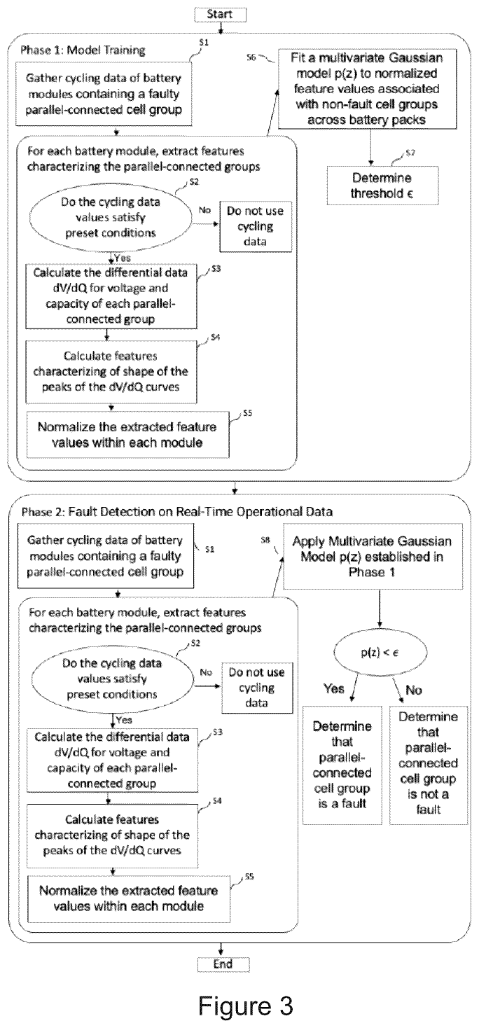

FIG. 3 shows a flow chart of a fault detection algorithm according to one non-limiting example method of the present invention. At step S1, cycling data includes voltage and current of each parallel-connected group in the battery pack. At step S2, cycling data must contain low-dynamic discharge or charge, such as under constant current or constant power conditions, where there is enough depth of charge or discharge such that the dV/dQ peaks are observable. At step S3, apply Savitzky-Golay (SG) filter to voltage data V(Q) and differentiate to get dV/dQ. At step S4, features that characterize the peaks of the dV/dQ include the peaks' height, skewness, width, location relative to voltage, and their daily changes.

At step S5:

Normalize feature values within each module

Apply z-score normalization for each feature, comparing them
$relative to the other cell groups within the same module . Let {x}_{c , m}^{i}$
$because the ith feature for cell c in module m and {z}_{c , m}^{i} be normalized$
value of this feature for cell c in module m. Let N=total number of
parallel-connected groups in series in a module.
for i = 1 to total number of features do
$\begin{matrix}{z}_{c , m}^{i} = \frac{{x}_{c , m}^{i} - {μ}_{m}^{i}}{{σ}_{m}^{i}} . \\ where \\ {μ}_{m}^{i} = \frac{1}{N} {\sum }_{c = 1}^{N} {x}_{c , m}^{i} . \\ {σ}_{m}^{i} = \sqrt{\frac{1}{N} {\sum }_{c = 1}^{N} {( {x}_{c , m}^{i} - {μ}_{m}^{i} )}^{2} .}\end{matrix}$
end for

At step S6:

Fit Multivariate Gaussian Model
Fit a Multivariate Gaussian model, p(z), to the to normalized feature
values {z¹, ... ,z^{N}} associated with non-fault cell groups. N = # of features.
$The rows of {z}^{i} consist {z}_{c , m}^{i} for c = 1 to total number of parallel ‐$
connected groups in series in a module, and m=1 to total number of
modules, where c, m is not a fault cell
Multivariate Gaussian model
$p ( z ; μ , Σ ) = \frac{1}{{( 2 π )}^{\frac{n}{2}} {\vert Σ \vert}^{\frac{1}{2}}} exp ( - \frac{1}{2} {( z - μ )}^{T} {Σ}^{- 1} ( z - μ ) )$
where parameters μ and Σ are defined as:
$\begin{matrix}μ = \frac{1}{N} {\sum }_{i = 1}^{N} {z}^{( i )} . \\ Σ = \frac{1}{N} {\sum }_{i = 1}^{N} ( {z}^{( i )} - μ ) {( {z}^{( i )} - μ )}^{T} .\end{matrix}$

At step S7:

Determine ϵ

```
Let
  • TP(ϵᵢ) be the number of true positives for ϵᵢ
  • FN(ϵᵢ) be the number of false negatives for ϵᵢ
  • FP(ϵᵢ) be the number of false positives for ϵᵢ
  $\begin{matrix} Recall ( {ϵ}_{i} ) = \frac{TP ( {ϵ}_{i} )}{TP ( {ϵ}_{i} ) + FN ( {ϵ}_{i} )} \\ Precision ( {ϵ}_{i} ) = \frac{TP ( {ϵ}_{i} )}{TP ( {ϵ}_{i} ) + FP ( {ϵ}_{i} )}\end{matrix}$
Filter: Find the set E = {ϵᵢ|Precision(ϵᵢ) ≥ 0.15}
$Maximize : Select {ϵ}_{optimal} = arg {max}_{{ϵ}_{i} ∈ E} ( Recall ( {ϵ}_{i} ) ) :$
```

At step S8, the input, z, into the model are the normalized extracted feature values for each parallel-connected group found in S5 in Phase 2.

The present invention provides an electrical device comprising: a battery module including one or more groups of parallel-connected battery cells; a voltage sensor operatively coupled to each group of parallel-connected battery cells in order to measure a voltage level of each group of parallel-connected battery cells; a current sensor operatively coupled to each group of parallel-connected battery cells in order to measure an amount of current drawn from each group of parallel-connected battery cells; and a battery management system including a controller in electrical communication with each voltage sensor and each current sensor. The controller can be configured to execute a program stored in the controller to: (i) receive a plurality of voltage values from each voltage sensor, (ii) receive a plurality of current values from each current sensor, wherein each current value is associated with one of the voltage values, (iii) calculate a plurality of total discharge values for each group of parallel-connected battery cells, wherein each total discharge value is associated with one of the current values, (iv) calculate a differential voltage curve for each group of parallel-connected battery cells using the voltage values and the total discharge values, (v) determine a differential voltage point on the differential voltage curve for each group of parallel-connected battery cells wherein each differential voltage point is at a local peak; (vi) determine one or more shape characteristics from differential voltage data surrounding each local peak; and (vii) pass each shape characteristic of each local peak into a model to detect or rule out a fault characteristic in each group of parallel-connected battery cells, the model including shape characteristics of local peaks of one or more differential voltage curves from one or more reference battery modules.

In one embodiment, the controller executes the program stored in the controller to: (iii) calculate the plurality of total discharge values from end of voltage relaxation values for each group of parallel-connected battery cells. In another embodiment, the controller executes the program stored in the controller to: (iii) calculate the plurality of total discharge values for each group of parallel-connected battery cells by coulomb counting. In one embodiment, the program stored in the controller only uses voltage values and current values to calculate each differential voltage curve for each group of parallel-connected battery cells.

In one embodiment, the controller executes the program stored in the controller determine the differential voltage point on the differential voltage curve for each group of parallel-connected battery cells whenever the battery module undergoes low current rate-dynamic discharge or charge. In another embodiment, the controller executes the program stored in the controller determine the differential voltage point on the differential voltage curve for each group of parallel-connected battery cells whenever the battery module undergoes low current rate-dynamic discharge or charge under constant current conditions. In another embodiment, the controller executes the program stored in the controller to determine the differential voltage point on the differential voltage curve for each group of parallel-connected battery cells whenever the battery module undergoes low current rate-dynamic discharge or charge under constant power conditions.

In one embodiment of the electrical device, the one or more shape characteristics is one or more of: height of the local peak, skewness of the local peak, width of the local peak, location of the local peak relative to voltage, location of the local peak in capacity relative the fully charged condition, location of the local peak in capacity relative the fully discharged condition, location of the local peak relative to any other peaks in the differential voltage curve, and daily changes to the one or more shape characteristics.

In one embodiment, the controller executes the program stored in the controller to calculate each differential voltage curve for each group of parallel-connected battery cells with respect to capacity. In another embodiment, the controller executes the program stored in the controller to calculate each differential voltage curve for each group of parallel-connected battery cells with respect to voltage. In one embodiment, the reference battery module includes at least one non-fault group of parallel-connected battery cells and at least one fault group of parallel-connected battery cells.

In one embodiment of the electrical device, the model is a trained statistical model trained on the one or more differential voltage curves obtained from the reference battery module. In one embodiment, the trained statistical model includes a multivariate Gaussian model fit to normalized one or more shape characteristics associated with the at least one non-fault group of parallel-connected battery cells from the reference battery module.

In one embodiment of the electrical device, the controller executes the program stored in the controller to normalize the one or more shape characteristics within the battery module, and the controller executes the program stored in the controller to detect or rule out a fault characteristic in each group of parallel-connected battery cells by applying the normalized one or more shape characteristics within the battery module to the multivariate Gaussian model of the trained statistical model. In one embodiment of the electrical device, the controller executes the program stored in the controller to detect a fault characteristic when a shape characteristic of a local peak is below a threshold.

In one embodiment, the differential voltage curve has local peaks originating from an anode. In one embodiment, the differential voltage curve has local peaks originating from a cathode.

In one embodiment of the electrical device, the reference battery module includes one or more groups of parallel-connected battery cells wherein each battery cell includes a cathode comprising an active material selected from the group consisting of lithium metal phosphates, lithium metal oxides, or any combination thereof. In one embodiment, the reference battery module includes one or more groups of parallel-connected battery cells wherein each battery cell includes an anode comprising an active material selected from the group consisting of graphite, lithium titanate, hard carbon, tin/cobalt alloy, and silicon carbon.

In one embodiment of the electrical device, the controller executes the program stored in the controller to: (vi) determine one or more shape characteristics from differential voltage data surrounding each local peak using data in a range that includes a state of charge phase transition.

The present invention also provides a method for detecting or ruling out a fault in a battery module including one or more groups of parallel-connected battery cells. The method comprises: (a) measuring voltage in each group of parallel-connected battery cells; (b) measuring current drawn from each group of parallel-connected battery cells; and (c) detecting or ruling out in a controller a fault characteristic in each group of parallel-connected battery cells based on: (i) the voltage measured, (ii) the current measured, (iii) a total discharge calculated, (iv) a differential voltage curve calculated based on the voltage measured and the total discharge calculated, (v) a differential voltage point on the differential voltage curve for each group of parallel-connected battery cells wherein each differential voltage point is at a local peak, wherein each local peak has a shape with one or more shape characteristics, and (vi) a comparison of each shape characteristic of each local peak to a predetermined shape characteristic in a model, wherein the model includes shape characteristics of local peaks of one or more differential voltage curves from one or more reference battery modules.

In one embodiment of the method, the controller determines the total discharge from end of voltage relaxation values for each group of parallel-connected battery cells. In one embodiment of the method, the controller determines the total discharge by coulomb counting. In one embodiment of the method, the controller only uses voltage values and current values to calculate each differential voltage curve for each group of parallel-connected battery cells.

In one embodiment of the method, the controller determines the differential voltage point on the differential voltage curve for each group of parallel-connected battery cells whenever the battery module undergoes low current rate-dynamic discharge or charge. In one embodiment of the method, the controller determines the differential voltage point on the differential voltage curve for each group of parallel-connected battery cells whenever the battery module undergoes low current rate-dynamic discharge or charge under constant current conditions. In one embodiment of the method, the controller determines the differential voltage point on the differential voltage curve for each group of parallel-connected battery cells whenever the battery module undergoes low current rate-dynamic discharge or charge under constant power conditions. In one embodiment of the method, the one or more shape characteristics is one or more of: height of the local peak, skewness of the local peak, width of the local peak, location of the local peak relative to voltage, location of the local peak in capacity relative the fully charged condition, location of the local peak in capacity relative the fully discharged condition, location of the local peak relative to any other peaks in the differential voltage curve, and daily changes to the one or more shape characteristics.

In one embodiment of the method, the controller calculates each differential voltage curve for each group of parallel-connected battery cells with respect to capacity. In one embodiment of the method, the controller calculates each differential voltage curve for each group of parallel-connected battery cells with respect to voltage.

In one embodiment of the method, the reference battery module includes at least one non-fault group of parallel-connected battery cells and at least one fault group of parallel-connected battery cells. In one embodiment of the method, the model is a trained statistical model trained on one or more differential voltage curves obtained from the reference battery module. In one embodiment of the method, the trained statistical model includes a multivariate Gaussian model fit to normalized one or more shape characteristics associated with the at least one non-fault group of parallel-connected battery cells from the reference battery module. In one embodiment of the method, the controller normalizes the one or more shape characteristics within the battery module, and the controller detects or rules out a fault characteristic in each group of parallel-connected battery cells by applying the normalized one or more shape characteristics within the battery module to the multivariate Gaussian model of the trained statistical model.

In one embodiment of the method, the controller executes the program stored in the controller to detect a fault characteristic when a shape characteristic of a local peak is below a threshold. In one embodiment of the method, the differential voltage curve for each group of parallel-connected battery cells has local peaks originating from an anode. In one embodiment of the method, the differential voltage curve for each group of parallel-connected battery cells has local peaks originating from a cathode.

In one embodiment of the method, the reference battery module includes one or more groups of parallel-connected battery cells wherein each battery cell includes a cathode comprising an active material selected from the group consisting of lithium metal phosphates, lithium metal oxides, or any combination thereof. In one embodiment of the method, the reference battery module includes one or more groups of parallel-connected battery cells wherein each battery cell includes an anode comprising an active material selected from the group consisting of graphite, lithium titanate, hard carbon, tin/cobalt alloy, and silicon carbon. In one embodiment of the method, the controller executes the program stored in the controller to: determine one or more shape characteristics from differential voltage data surrounding each local peak using data in a range that includes a state of charge phase transition.

The present invention also provides a method in a data processing system comprising at least one processor and at least one memory, the at least one memory comprising instructions executed by the at least one processor to implement a battery module fault detection system. The method comprises: (a) receiving a plurality of voltage values from a voltage sensor operatively coupled to each group of parallel-connected battery cells of a battery module in order to measure a voltage level of each group of parallel-connected battery cells; (b) receiving a plurality of current values from a current sensor operatively coupled to each group of parallel-connected battery cells in order to measure an amount of current drawn from each group of parallel-connected battery cells, each current value being associated with one of the voltage values included in the plurality of voltage values; (c) calculating a plurality of total discharge values, each total discharge value being associated with one of the current values included in the plurality of current values; (d) calculating a differential voltage curve based on the voltage values and the total discharge values; (e) determining a differential voltage point on the differential voltage curve for each group of parallel-connected battery cells wherein each differential voltage point is at a local peak, wherein each local peak has a shape with one or more shape characteristics; and (f) passing each shape characteristic of each local peak into a model to detect or rule out a fault characteristic in each group of parallel-connected battery cells, the model including the shape characteristics of local peaks of one or more differential voltage curves from one or more reference battery modules.

In one embodiment of the method in the data processing system, the method determines the total discharge from end of voltage relaxation values for each group of parallel-connected battery cells. In one embodiment of the method in the data processing system, the method determines the total discharge by coulomb counting. In one embodiment of the method in the data processing system, the method only uses voltage values and current values to calculate each differential voltage curve for each group of parallel-connected battery cells. In one embodiment of the method in the data processing system, the method determines the differential voltage point on the differential voltage curve for each group of parallel-connected battery cells whenever the battery module undergoes low current rate-dynamic discharge or charge.

In one embodiment of the method in the data processing system, the method determines the differential voltage point on the differential voltage curve for each group of parallel-connected battery cells whenever the battery module undergoes low current rate-dynamic discharge or charge under constant current conditions. In one embodiment of the method in the data processing system, the method determines the differential voltage point on the differential voltage curve for each group of parallel-connected battery cells whenever the battery module undergoes low current rate-dynamic discharge or charge under constant power conditions.

In one embodiment of the method in the data processing system, the one or more shape characteristics is one or more of: height of the local peak, skewness of the local peak, width of the local peak, location of the local peak relative to voltage, location of the local peak in capacity relative the fully charged condition, location of the local peak in capacity relative the fully discharged condition, location of the local peak relative to any other peaks in the differential voltage curve, and daily changes to the one or more shape characteristics.

In one embodiment of the method in the data processing system, the method calculates each differential voltage curve for each group of parallel-connected battery cells with respect to capacity. In one embodiment of the method in the data processing system, the method calculates each differential voltage curve for each group of parallel-connected battery cells with respect to voltage.

In one embodiment of the method in the data processing system, the reference battery module includes at least one non-fault group of parallel-connected battery cells and at least one fault group of parallel-connected battery cells. In one embodiment of the method in the data processing system, the model is a trained statistical model trained on one or more differential voltage curves obtained from the reference battery module. In one embodiment of the method in the data processing system, the trained statistical model includes a multivariate Gaussian model fit to normalized one or more shape characteristics associated with the at least one non-fault group of parallel-connected battery cells from the reference battery module.

In one embodiment of the method in the data processing system, the method normalizes the one or more shape characteristics within the battery module, and the method detects or rules out a fault characteristic in each group of parallel-connected battery cells by applying the normalized one or more shape characteristics within the battery module to the multivariate Gaussian model of the trained statistical model. In one embodiment of the method in the data processing system, the method detects a fault characteristic when a shape characteristic of a local peak is below a threshold.

In one embodiment of the method in the data processing system, the differential voltage curve for each group of parallel-connected battery cells has local peaks originating from an anode. In one embodiment of the method in the data processing system, the differential voltage curve for each group of parallel-connected battery cells has local peaks originating from a cathode. In one embodiment of the method in the data processing system, the method further comprises determining one or more shape characteristics from differential voltage data surrounding each local peak using data in a range that includes a state of charge phase transition.

### EXAMPLE

The following Examples have been presented in order to further illustrate the invention and are not intended to limit the invention in any way. The statements provided in the Examples are presented without being bound by theory.

### Example 1

### 1. Fault Detection Algorithm

Algorithm Overview: This algorithm is designed for fault detection of cell groups in modules by leveraging multivariate Gaussian models. It operates in two main phases: Model Training and Fault Detection on real-time operational data.

### 1.1 Phase 1: Model Training

1. Gather cycling data (6 months before fault) of modules containing a faulty cell group. These modules will serve as the training set.

2. Feature Extraction:

Feature Extraction

Definitions:
$Let {H}_{c , m , d} be the estimated cell low SOC \frac{dV}{dQ} height on day d for cell$
c in module m.
Let C_{c,m,d} be the estimated cell capacity on day d for cell c in module m.
Let f be the day of the fault.
$Let the slope \{ {x}_{c , m , d} \vert i \leq d < j \} = \frac{{\sum }_{d = i}^{j - 1} ( {z}_{c , m , d} - \overline{x} ) ( {y}_{d} - \overline{y} )}{{\sum }_{d = i}^{j - 1} {( {x}_{c , m , d} - \overline{x} )}^{2}}$ [symbol]
Applying linear regression to the data from days i to j − 1, extracting
the slope coefficient from the regression model.
Extract the following features:
$1. {x}_{c , m}^{1} = med \{ {H}_{c , m , d} \vert f - 30 \leq d < f \} ⊳ Median Low SOC \frac{dV}{dQ} height$
over the last 30 days of cycling prior to fault for cell c in module m.
$2. {x}_{c , m}^{2} = med \{ {C}_{c , m , d} \vert f - 30 \leq d < f \} ⊳ Median Capacity over the last$
30 days of cycling prior to fault for cell c in module m.
$3. {x}_{c , m}^{3} = slope \{ {H}_{c , m , d} \vert f - 180 \leq d < f \} ⊳ Slope of Low SOC Height$
derived from 180 days of cycling before fault for c in module m.
$4. {x}_{c , m}^{4} = slope \{ {C}_{c , m , d} \vert f - 180 \leq d < f \} ⊳ Slope of Capacity derived$
from 180 days of cycling before fault for c in module m.

3. Normalize the extracted feature values within each module.

Normalize feature values within each module

Apply z-score normalization for each feature, comparing them relative to
the other cell groups within the same module.
for i = 1 to 4 do
$\begin{matrix}{z}_{c , m}^{i} = \frac{{x}_{c , m}^{i} - {μ}_{m}^{i}}{{σ}_{m}^{i}} . \\ where \\ {μ}_{m}^{i} = \frac{1}{N} {\sum }_{c = 1}^{N} {x}_{c , m}^{i} , where N = 14. \\ {σ}_{m}^{i} = \sqrt{\frac{1}{N} {\sum }_{c = 1}^{N} {( {x}_{c , m}^{i} - {μ}_{m}^{i} )}^{2}} , where N = 14.\end{matrix}$
end for

4. Fit a multivariate Gaussian model p(z) to normalized feature values associated with non-fault cell groups.

Fit Multivariate Gaussian Model
Fit a Multivariate Gaussian model, p(z), to the to normalized feature
values {z¹, ... ,z^{N}} associated with non-fault cell groups. N = # of
features = 4.
$The rows of {z}^{i} consist {z}_{c , m}^{i} for c = 1 to 14 , and m = 1 to 25 , where c , m$
is not a fault cell
Multivariate Gaussian model
$p ( z ; μ , Σ ) = \frac{1}{{( 2 π )}^{\frac{n}{2}} {\vert Σ \vert}^{\frac{1}{2}}} exp ( - \frac{1}{2} {( z - μ )}^{T} {Σ}^{- 1} ( z - μ ) )$
where parameters μ and Σ are defined as:
$\begin{matrix}μ = \frac{1}{N} {\sum }_{i = 1}^{N} {z}^{( i )} , & where N = 4. \\ Σ = \frac{1}{N} {\sum }_{i = 1}^{N} ( {z}^{( i )} - μ ) {( {z}^{( i )} - μ )}^{T} , & where N = 4.\end{matrix}$

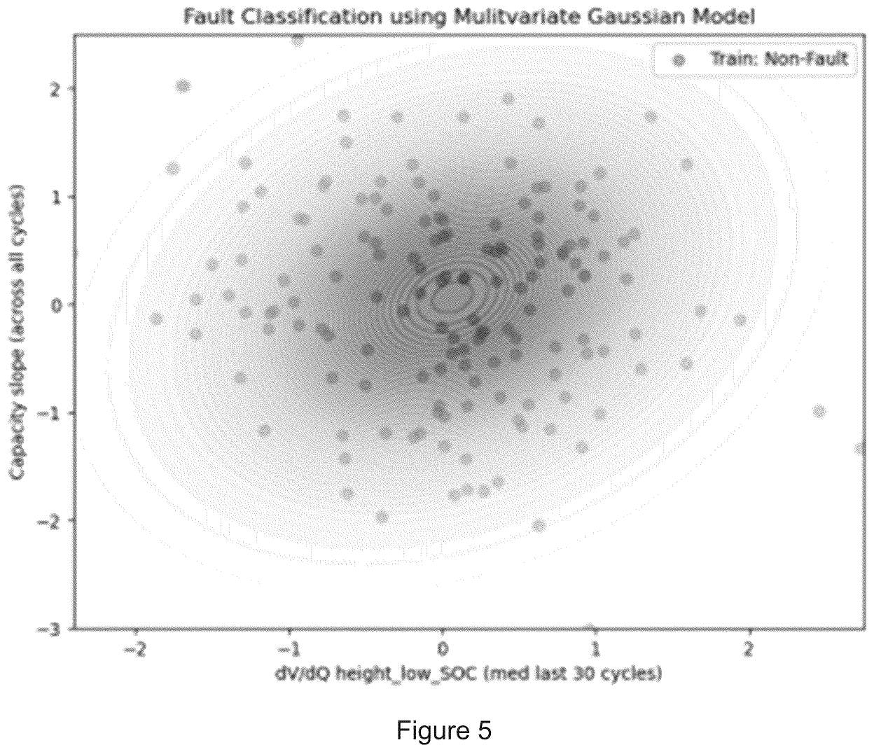

FIG. 5 shows fault classification using the multivariate Gaussian model.

5. Determine threshold ϵ.
a. Algorithm flags fault when p(z)<ϵ.
b. ϵ is determined for optimizing for recall while maintaining a minimum precision of 15%.

Determine ϵ

```
Let
  • TP(ϵᵢ) be the number of true positives for ϵᵢ
  • FN(ϵᵢ) be the number of false negatives for ϵᵢ
  • FP(ϵᵢ) be the number of false positives for ϵᵢ
$\begin{matrix}Recall ( {ϵ}_{i} ) = \frac{TP ( {ϵ}_{i} )}{TP ( {ϵ}_{i} ) + FN ( {ϵ}_{i} )} \\ Precision ( {ϵ}_{i} ) = \frac{TP ( {ϵ}_{i} )}{TP ( {ϵ}_{i} ) + FP ( {ϵ}_{i} )}\end{matrix}$
Filter: Find the set E = {ϵᵢ|Precision(ϵᵢ) ≥ 0.15}
$Maximize : Select {ϵ}_{optimal} = arg {max}_{{ϵ}_{i} ∈ E} ( Recall ( {ϵ}_{i} ) )$
```

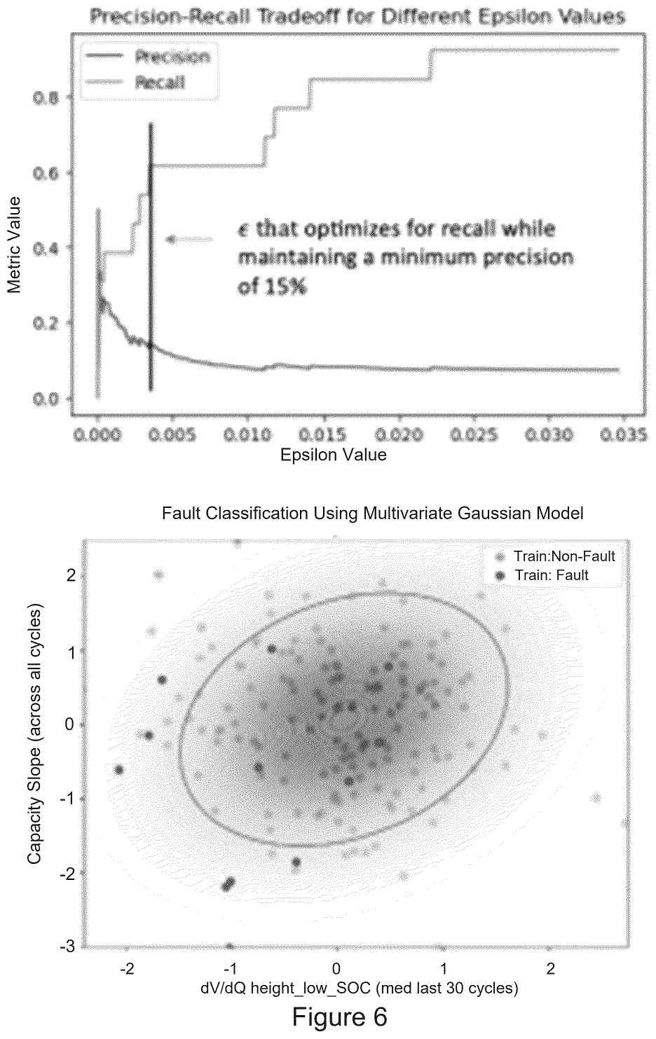

FIG. 6 shows in the left panel, precision-recall tradeoff for different epsilon values, and in the right panel, fault classification using a multivariate Gaussian model from the model training phase.

### 1.2 Phase 2: Fault Detection on Real-Time Operational Data

1. Feature Extraction
a. For a module in operation, extract the following features:

Feature Extraction

Definitions:
Let r be the current operational day.
Extract the following features:
$1. {x}_{c , m}^{1} = med \{ {H}_{c , m , d} \vert r - 30 \leq d < r \} ⊳ Median Low SOC \frac{dV}{dQ} height$
over the most recent 30 days for cell c in module m.
$2. {x}_{c , m}^{2} = med \{ {C}_{c , m , d} \vert r - 30 \leq d < r \} ⊳ Median Capacity over the most$
recent 30 days for cell c in module m.
$3. {x}_{c , m}^{3} = slope \{ {H}_{c , m , d} \vert r - 180 \leq d < r \} ⊳ Slope of Low SOC Height$
derived from from most recent 180 days for c in module m.
$4. {x}_{c , m}^{4} = slope \{ {C}_{c , m , d} \vert r - 180 \leq d < r \} ⊳ Slope of Capacity derived$
from most recent 180 days for c in module m.

2. Normalize the extracted feature values within each module.
a. Similar to in Phase 1

Normalize feature values within each module

Apply z-score normalization for each feature, comparing them relative to
the other cell groups within the same module.
for i = 1 to 4 do
$\begin{matrix}{z}_{c , m}^{i} = \frac{{x}_{c , m}^{i} - {μ}_{m}^{i}}{{σ}_{m}^{i}} . \\ where \\ {μ}_{m}^{i} = \frac{1}{N} {\sum }_{c = 1}^{N} {x}_{c , m}^{i} , where N = 14. \\ {σ}_{m}^{i} = \sqrt{\frac{1}{N} {\sum }_{c = 1}^{N} {( {x}_{c , m}^{i} - {μ}_{m}^{i} )}^{2}} , where N = 14.\end{matrix}$
end for

3. Apply Multivariate Gaussian Model p(z) established in Phase 1 where

the input, z, into the model are the normalized extracted feature values for each cell group.

```
Apply Multivariate Gaussian Model p(z) established in Phase 1 to input test data
{z¹, ... , z⁴}
  From Phase 2.1 and 2.2
  ${z}^{1} = Normalized Median Low SOC \frac{dV}{dQ} height over the most recent 30 days$
  z² = Normalized Median Capacity over the most recent 30 days
  z³ = Normalized Slope of Low SOC Height derived from from most recent
  180 days
  z⁴ = Normalized Slope of Capacity derived from from most recent 180 days
```

4. Flag if the cell group is a fault.

$$Fault or Non ‐ fault = \{ \begin{matrix}Fault & if p ( z ) < ε \\ Non ‐ fault & if p ( z ) \geq ε\end{matrix}$$

### Example 2

Algorithm Overview: This another algorithm for extracting dV/dQ peak shape features. This algorithm is designed for dV/dQ Shape Features Estimation Through Physics-Informed 2-Electrode Model Fitting. The data is constant current or constant power discharge or charge cell group Q and Vt that includes mid-to-high state of charge (SOC) dV/dQ peak, which is attributed to the Stage 2 phase transition in the graphite in the lithiation/delithiation process. Step 1 comprises downselecting data to the range that includes the mid-to-high SOC phase transition. Step 2 comprises estimating parameters of the Physics-Informed 2-Electrode Model. Step 3 comprises estimating dV/dQ shape features using the estimated parameters.

### Procedure

1. Downselect Data to the range that includes the mid-to-high SOC phase transition
2. Estimate parameters of the Physics-Informed 2-Electrode Model The Physics-Informed 2-Electrode Model is formulated as follows:

$${\hat{V}}_{t} ( Q , θ ) = P ( Q ; a , b , c ) - N ( Q ; h , w , p , s )$$

where
   P(Q; a, b, c) represents the cell group positive electrode potential, modeled as:

$$P ( Q ; a , b , c ) = a + b \cdot Q + c \cdot {Q}^{2}$$

N(Q; h, w, p, s) represents the cell group negative electrode potential, modeled as:

$$N ( Q ; h , w , p , s ) = \frac{- h}{{( 1 + {e}^{- w ( Q - p )} )}^{s}}$$

Estimate parameters θ={a, b, c, h, w, p, s} by minimizing the following:

$$\hat{θ} = {arg min}_{θ} {‖ {V}_{t} ( Q ; θ ) - {V}_{t} ‖}^{2}$$

3. Estimate dV/dQ shape features using the estimated parameters ĥ, ŵ, ŝ, \hat{p}.
   dV/dQ Peak Height=ĥ·ŵ·2^{-1-ŝ}·ŝ
   dV/dQ Peak Width=ŵ
   dV/dQ Peak Skewness=ŝ
   dV/dQ Peak Location=\hat{p}

Thus, the invention provides improved devices and methods for detecting or ruling out a fault in a battery module including one or more battery cells.

In light of the principles and example embodiments described and illustrated herein, it will be recognized that the example embodiments can be modified in arrangement and detail without departing from such principles. Also, the foregoing discussion has focused on particular embodiments, but other configurations are also contemplated. In particular, even though expressions such as “in one embodiment”, “in another embodiment,” or the like are used herein, these phrases are meant to generally reference embodiment possibilities, and are not intended to limit the invention to particular embodiment configurations. As used herein, these terms may reference the same or different embodiments that are combinable into other embodiments. As a rule, any embodiment referenced herein is freely combinable with any one or more of the other embodiments referenced herein, and any number of features of different embodiments are combinable with one another, unless indicated otherwise.

Although the invention has been described in considerable detail with reference to certain embodiments, one skilled in the art will appreciate that the present invention can be practiced by other than the described embodiments, which have been presented for purposes of illustration and not of limitation. Therefore, the scope of the appended claims should not be limited to the description of the embodiments contained herein.

1. An electrical device comprising:
a battery module including one or more groups of parallel-connected battery cells;
a voltage sensor operatively coupled to each group of parallel-connected battery cells in order to measure a voltage level of each group of parallel-connected battery cells;
a current sensor operatively coupled to each group of parallel-connected battery cells in order to measure an amount of current drawn from each group of parallel-connected battery cells; and
a battery management system including a controller in electrical communication with each voltage sensor and each current sensor, the controller being configured to execute a program stored in the controller to:
(i) receive a plurality of voltage values from each voltage sensor,
(ii) receive a plurality of current values from each current sensor, wherein each current value is associated with one of the voltage values,
(iii) calculate a plurality of total discharge values for each group of parallel-connected battery cells, wherein each total discharge value is associated with one of the current values,
(iv) calculate a differential voltage curve for each group of parallel-connected battery cells using the voltage values and the total discharge values,
(v) determine a differential voltage point on the differential voltage curve for each group of parallel-connected battery cells wherein each differential voltage point is at a local peak;
(vi) determine one or more shape characteristics from differential voltage data surrounding each local peak; and
(vii) pass each shape characteristic of each local peak into a model to detect or rule out a fault characteristic in each group of parallel-connected battery cells, the model including shape characteristics of local peaks of one or more differential voltage curves from one or more reference battery modules.

2. The electrical device of claim 1 wherein:
the controller executes the program stored in the controller to:
(iii) calculate the plurality of total discharge values from end of voltage relaxation values for each group of parallel-connected battery cells.

3. The electrical device of claim 1 wherein:
the controller executes the program stored in the controller to:
(iii) calculate the plurality of total discharge values for each group of parallel-connected battery cells by coulomb counting.

4. The electrical device of claim 1 wherein:
the program stored in the controller only uses voltage values and current values to calculate each differential voltage curve for each group of parallel-connected battery cells.

5. The electrical device of claim 1 wherein:
the controller executes the program stored in the controller determine the differential voltage point on the differential voltage curve for each group of parallel-connected battery cells whenever the battery module undergoes low current rate-dynamic discharge or charge.

6. The electrical device of claim 1 wherein:
the controller executes the program stored in the controller determine the differential voltage point on the differential voltage curve for each group of parallel-connected battery cells whenever the battery module undergoes low current rate-dynamic discharge or charge under constant current conditions.

7. The electrical device of claim 1 wherein:
the controller executes the program stored in the controller to determine the differential voltage point on the differential voltage curve for each group of parallel-connected battery cells whenever the battery module undergoes low current rate-dynamic discharge or charge under constant power conditions.

8. The electrical device of claim 1 wherein:
the one or more shape characteristics is one or more of:
height of the local peak,
skewness of the local peak,
width of the local peak,
location of the local peak relative to voltage,
location of the local peak in capacity relative the fully charged condition,
location of the local peak in capacity relative the fully discharged condition,
location of the local peak relative to any other peaks in the differential voltage curve, and
daily changes to the one or more shape characteristics.

9. The electrical device of claim 1 wherein:
the controller executes the program stored in the controller to calculate each differential voltage curve for each group of parallel-connected battery cells with respect to capacity.

10. The electrical device of claim 1 wherein:
the controller executes the program stored in the controller to calculate each differential voltage curve for each group of parallel-connected battery cells with respect to voltage.

11. The electrical device of claim 1 wherein:
the reference battery module includes at least one non-fault group of parallel-connected battery cells and at least one fault group of parallel-connected battery cells.

12. (canceled)

13. (canceled)

14. (canceled)

15. (canceled)

16. The electrical device of claim 1 wherein:
the differential voltage curve has local peaks originating from an anode.

17. The electrical device of claim 1 wherein:
the differential voltage curve has local peaks originating from a cathode.

18. The electrical device of claim 1 wherein:
the reference battery module includes one or more groups of parallel-connected battery cells wherein each battery cell includes a cathode comprising an active material selected from the group consisting of lithium metal phosphates, lithium metal oxides, or any combination thereof.

19. The electrical device of claim 1 wherein:
the reference battery module includes one or more groups of parallel-connected battery cells wherein each battery cell includes an anode comprising an active material selected from the group consisting of graphite, lithium titanate, hard carbon, tin/cobalt alloy, and silicon carbon.

20. The electrical device of claim 1 wherein:
the controller executes the program stored in the controller to:
(vi) determine one or more shape characteristics from differential voltage data surrounding each local peak using data in a range that includes a state of charge phase transition.

21. A method for detecting or ruling out a fault in a battery module including one or more groups of parallel-connected battery cells, the method comprising:
(a) measuring voltage in each group of parallel-connected battery cells;
(b) measuring current drawn from each group of parallel-connected battery cells; and
(c) detecting or ruling out in a controller a fault characteristic in each group of parallel-connected battery cells based on: (i) the voltage measured, (ii) the current measured, (iii) a total discharge calculated, (iv) a differential voltage curve calculated based on the voltage measured and the total discharge calculated, (v) a differential voltage point on the differential voltage curve for each group of parallel-connected battery cells wherein each differential voltage point is at a local peak, wherein each local peak has a shape with one or more shape characteristics, and (vi) a comparison of each shape characteristic of each local peak to a predetermined shape characteristic in a model, wherein the model includes shape characteristics of local peaks of one or more differential voltage curves from one or more reference battery modules.

22. The method of claim 21 wherein:
the controller determines the total discharge from end of voltage relaxation values for each group of parallel-connected battery cells.

23. The method of claim 21 wherein:
the controller determines the total discharge by coulomb counting.

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. A method in a data processing system comprising at least one processor and at least one memory, the at least one memory comprising instructions executed by the at least one processor to implement a battery module fault detection system, the method comprising:
(a) receiving a plurality of voltage values from a voltage sensor operatively coupled to each group of parallel-connected battery cells of a battery module in order to measure a voltage level of each group of parallel-connected battery cells;
(b) receiving a plurality of current values from a current sensor operatively coupled to each group of parallel-connected battery cells in order to measure an amount of current drawn from each group of parallel-connected battery cells, each current value being associated with one of the voltage values included in the plurality of voltage values;
(c) calculating a plurality of total discharge values, each total discharge value being associated with one of the current values included in the plurality of current values;
(d) calculating a differential voltage curve based on the voltage values and the total discharge values;
(e) determining a differential voltage point on the differential voltage curve for each group of parallel-connected battery cells wherein each differential voltage point is at a local peak, wherein each local peak has a shape with one or more shape characteristics; and
(f) passing each shape characteristic of each local peak into a model to detect or rule out a fault characteristic in each group of parallel-connected battery cells, the model including the shape characteristics of local peaks of one or more differential voltage curves from one or more reference battery modules.

42. (canceled)

43. (canceled)

44. (canceled)

45. (canceled)

46. (canceled)

47. (canceled)

48. (canceled)

49. (canceled)

50. (canceled)

51. (canceled)

52. (canceled)

53. (canceled)

54. (canceled)

55. (canceled)

56. (canceled)

57. (canceled)

58. (canceled)
